(19) United States
(12) Patent Application Publication
(10) Pub. No.: US 2025/0234741 A1
(43) Pub. Date: Jul. 17, 2025

(54) LIGHT-EMITTING MODULE AND LIGHT-EMITTING DEVICE

(71) Applicants: Chengdu BOE Optoelectronics Technology Co., Ltd., Chengdu, Sichuan (CN); BOE Technology Group Co., Ltd., Beijing (CN)

(72) Inventors: Chengjie QIN, Beijing (CN); Hongjun ZHOU, Beijing (CN); Fengli JI, Beijing (CN)

(21) Appl. No.: 18/701,629

(22) PCT Filed: Jul. 5, 2023
(86) PCT No.: PCT/CN2023/105833

§ 371 Date: Apr. 16, 2024

(30) Foreign Application Priority Data
Jul. 25, 2022 (CN) 202210879182.9

(51) Int. Cl. H10K 59/38; H10K 59/80

(52) U.S. Cl. CPC H10K 59/38; H10K 59/873; H10K 59/879

(57) ABSTRACT

The present disclosure provides a light-emitting module and a light-emitting device, and belongs to the technical field of lighting. A light-emitting module is disclosed, which comprises a first base substrate, and a functional layer and at least one light-emitting element disposed on the first base substrate; the light-emitting element is provided with a first electrode, a light-emitting layer and a second electrode in sequence on the functional layer in a direction away from the first base substrate; the functional layer is located on a side of the first electrode close to the first base substrate, and is configured to convert the light emitted by the light-emitting element into the light of a specific color; wherein the functional layer comprises N sub-functional layers disposed in sequence in a direction away from the first base substrate, and N≥3.

### CROSS-REFERENCE TO RELATED APPLICATIONS

The present application is a U.S. National Phase Entry of International Application No. PCT/CN2023/105833, having an international filing date of Jul. 5, 2023, which claims priority of Chinese Patent Application No. 202210879182.9, filed to the CNIPA on Jul. 25, 2022. The entire contents of above-identified applications are hereby incorporated by reference.

### TECHNICAL FIELD

The present disclosure belongs to the technical field of lighting, in particular, relates to a light-emitting module and a light-emitting device.

### BACKGROUND

Traditional taillight products usually use a light-emitting diode (LED). With the development of Organic Light-Emitting Diode (OLED), OLED has been paid more and more attention in the technical field of lighting because of its advantages such as self-luminescence, wide viewing angle, almost infinitely high contrast, low power consumption and extremely high response speed. At present, OLED products of taillights are more and more favored by the market and also more and more diversified.

With the development in the fields of lighting technology and automobile technology, the color of taillights has become varied. Therefore, without increasing the cost, for example, without increasing the cost of a mask, how to design taillight products with multiple colors to meet the diversified market needs has become a problem that needs to be solved nowadays.

### SUMMARY

The invention aims at solving at least one of the technical problems in the prior art, and provides a light-emitting module and a light-emitting device for realizing multi-color light emitting without increasing the cost of a mask.

In a first aspect, an embodiment of the present disclosure provides a light-emitting module, comprising a first base substrate, and a functional layer and at least one light-emitting element disposed on the first base substrate.

The light-emitting element is provided with a first electrode, a light-emitting layer and a second electrode in sequence on the functional layer in a direction away from the first base substrate.

The functional layer is located on a side of the first electrode close to the first base substrate, and is configured to convert the light emitted by the light-emitting element into the light of a specific color; wherein the functional layer comprises N sub-functional layers disposed in sequence in a direction away from the first base substrate, and N≥3.

The sub-functional layer comprises at least one first sub-functional layer and at least one second sub-functional layer; the first sub-functional layer and the second sub-functional layer are alternately arranged; and the refractive index of the first sub-functional layer is greater than the refractive index of the second sub-functional layer.

In the embodiment, a material of the first sub-functional layer is silicon nitride or silicon oxynitride.

In the embodiment, the refractive index of the material of the first sub-functional layer is 1.6-2.0.

In the embodiment, a material of the second sub-functional layer is silicon oxide.

In the embodiment, the refractive index of the material of the second sub-functional layer is 1.2-1.6.

In the embodiment, the functional layer comprises N sub-functional layers, and N≥3; and one of the sub-functional layers closest to the light-emitting element is the first sub-functional layer.

In the embodiment, the functional layer comprises N sub-functional layers, and N≥3; and one of the sub-functional layers closest to the light-emitting element is the second sub-functional layer.

In the embodiment, when the light-emitting color of the light-emitting module is orange, the functional layer comprises two layers of the first sub-functional layer and the second sub-functional layer sandwiched between the two layers of the first sub-functional layer; a thickness of the first sub-functional layer is 66 nm; and a thickness of the second sub-functional layer is 50 nm.

In the embodiment, when the light-emitting color of the light-emitting module is red, the functional layer comprises two layers of the first sub-functional layer and the second sub-functional layer sandwiched between the two layers of the first sub-functional layer; a thickness of the first sub-functional layer is 66 nm; and a thickness of the second sub-functional layer is 70 nm.

In the embodiment, the first electrode is a transparent electrode; and the second electrode is a reflecting electrode.

In the embodiment, the light-emitting module further comprises a second base substrate disposed opposite to the first base substrate and a reflecting layer disposed on a side of the second base substrate away from the light-emitting element.

An orthographic projection of the reflecting layer on the first base substrate covers an orthographic projection of the second electrode of each of the light-emitting elements on the first base substrate.

In the embodiment, the light-emitting module further comprises an encapsulation base and an encapsulation structure, which are positioned at an edge of the light-emitting module and disposed between the first base substrate and the second base substrate.

The encapsulation base is positioned on a side of the functional layer away from the first base substrate; and the second electrode of the light-emitting element positioned at the edge of the light-emitting module partially covers the encapsulation base.

The encapsulation structure is used for sealing the edge of the light-emitting module.

In the embodiment, the encapsulation base comprises a main body structure and a plurality of branch structures; and the encapsulation structure is at least partially embedded in a gap formed between the respective branch structures.

In a second aspect, an embodiment of the present disclosure provides a light-emitting device, comprising any one of the light-emitting module described above.

### BRIEF DESCRIPTION OF DRAWINGS

FIG. 1 is a schematic structural diagram of a light-emitting element provided by an embodiment of the present disclosure.

FIG. 2 is a schematic structural diagram of a light-emitting layer of a light-emitting element in an embodiment of the present disclosure.

FIG. 3 is a schematic structural diagram of a light-emitting module provided by an embodiment of the present disclosure.

FIG. 4 is a schematic structural diagram of a functional layer provided by an embodiment of the present disclosure.

In the drawings, the reference signs are: 101, a first base substrate; 102, a second base substrate; 103, a reflecting layer; 201, a functional layer; 2011, a first sub-functional layer; 2012, the second sub-functional layer; 202, an encapsulation base; 203, a first electrode; 204, a light-emitting layer; 205, a second electrode; 301, an encapsulation structure; HIL, a hole injection layer; HTL, a hole transport layer; EBL, an electron block layer; EML, an organic light-emitting layer; HBL, a hole block layer; ETL, an electron transport layer.

### DETAILED DESCRIPTION

To enable those skilled in the art to better understand the technical solutions of the present invention, a further detailed description of the present invention is given below in conjunction with the accompanying drawings and detailed description.

Unless otherwise defined, technical terms or scientific terms used in the present disclosure should have the meanings as commonly understood by those of ordinary skills in the art that the present disclosure belongs to. The “first”, “second” and similar terms used in the present disclosure do not indicate any order, quantity, or importance, but are used only for distinguishing different components. Similarly, similar words such as “a”, “an” or “the” do not denote a limitation on quantity, but rather denote the presence of at least one. “Include”, “comprise”, or similar words mean that elements or objects appearing before the words cover elements or objects listed after the words and their equivalents, but do not exclude other elements or objects. “Connect”, “couple”, or a similar term is not limited to a physical or mechanical connection, but may include an electrical connection, whether direct or indirect. “Upper”, “lower”, “left”, and “right”, etc., are used for representing relative positional relationships, and when an absolute position of a described object is changed, a relative positional relationship may also be correspondingly changed.

The light-emitting element used in a light-emitting module is usually a Light-Emitting Diode (LED). With the development of Organic Light-Emitting Diode (OLED), organic light-emitting diode has the advantages such as self-luminescence, wide viewing angle, almost infinitely high contrast, low power consumption, extremely high response speed, and is gradually used in the field of lighting technology. Meanwhile, in the automobile market, the requirements for the lighting quality of taillights are getting higher and higher. Therefore, organic light-emitting diode products of taillights are getting more and more popular, and taillights with multiple colors are also favored by everyone. How to design taillights with multiple colors without additionally increasing the cost has become a problem that needs to be solved nowadays.

In view of this, an embodiment of the present disclosure provides a taillight product with multiple colors without additional cost of a mask. If the organic light-emitting diodes are improved to have multiple colors, the process flow and the number of masks may be increased. Masks occupy a certain amount of cost in the production of the organic light-emitting diodes. The light-emitting modules in the embodiments of the present disclosure can be produced with multiple colors without adding a mask and a process flow, and can be used for taillight products, making the taillight to have multiple colors.

The light-emitting modules of the embodiments of the present disclosure are described below with reference to the drawings and specific embodiments.

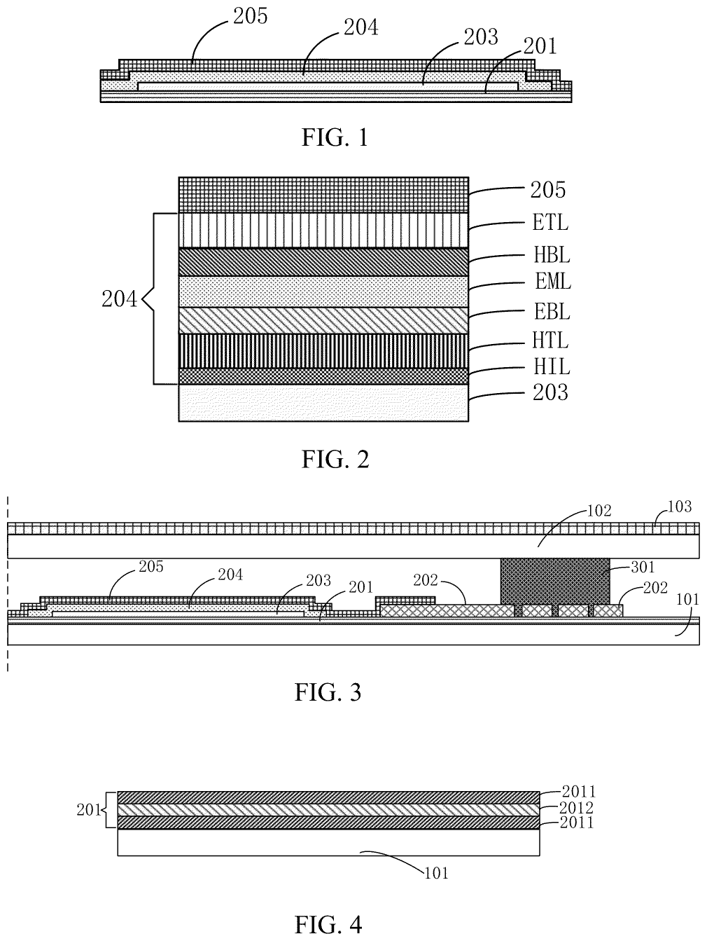

In the first aspect, an embodiment of the present disclosure discloses a light-emitting module. FIG. 1 is a schematic structural diagram of a light-emitting element provided by an embodiment of the present disclosure, FIG. 2 is a schematic structural diagram of a light-emitting layer of a light-emitting element in an embodiment of the present disclosure, and FIG. 3 is a schematic structural diagram of a light-emitting module provided by an embodiment of the present disclosure. As shown in FIGS. 1-3, the light-emitting module comprises a first base substrate 101, and a functional layer 201 and at least one light-emitting element disposed on the first base substrate 101. The at least one light-emitting element is provided with a first electrode 203, a light-emitting layer 204 and a second electrode 205 in sequence on the functional layer 201. The functional layer 201 is configured to convert the light emitted by the light-emitting element into the light of a specific color, and is provided with at least three sub-functional layers in sequence in a direction away from the first base substrate 101.

The light-emitting element in the embodiments of the present disclosure is Organic Light-Emitting Diode (OLED). The structure of the organic light-emitting diode comprises an anode, a light-emitting layer 204 and a cathode that are disposed on a base substrate in sequence, in which the light-emitting layer 204 comprises a hole injection layer HIL, a hole transport layer HTL, an electron block layer EBL, an organic light-emitting layer EML, a hole block layer HBL and an electron transport layer ETL. After voltage is applied to the anode and the cathode, holes and electrons are injected from the anode and the cathode respectively, enter the HOMO (highest occupied molecular orbital) energy level of the hole transport layer HTL and the LUMO (lowest unoccupied molecular orbital) energy level of the electron transport layer ETL respectively, and then transition to the organic light-emitting layer EML to meet each other and form electron-hole pairs, i.e., excitons. Excitons in the excited state of molecules are released in the form of photons, emitting visible light.

There are two types of organic light-emitting diode, which are top-emitting organic light-emitting diode and bottom-emitting organic light-emitting diode. The light-emitting direction of the top-emitting organic light-emitting diode is emitting in the direction away from the base substrate, that is, light emits from the cathode side. The top-emitting organic light-emitting diode is provided with an anode, a hole injection layer HIL, a hole transport layer HTL, an electron block layer EBL, an organic light-emitting layer EML, a hole block layer HBL, an electron transport layer ETL and a cathode in sequence on a base substrate. The anode of the top-emitting organic light-emitting diode is a metal electrode with certain light reflectivity; the cathode thereof is a translucent or transparent electrode; and the first base substrate 101 thereof may be a metal, an organic synthetic material and an inorganic synthetic material. The bottom-emitting organic light-emitting diode has an opposite light-emitting direction with the top-emitting organic light-emitting diode, emitting light in the direction close to the base substrate, that is, emitting light from the side of the base substrate. The bottom-emitting organic light-emitting diode is provided with an anode, a hole injection layer HIL, a hole transport layer HTL, an electron block layer EBL, an organic light-emitting layer EML, a hole block layer HBL, an electron transport layer ETL and a cathode in sequence on the first base substrate 101. The anode of the bottom-emitting organic light-emitting diode is a transparent electrode with good light emission; and the cathode thereof is a reflecting electrode, which can reflect most of the light so that the light can be emitted from a side of the base substrate. Usually, a material with excellent light-transmitting effect, such as glass or light-transmitting film or the like, is used for the base substrate.

It should be noted that during the light-emitting process of the bottom-emitting organic light-emitting diode, a part of the light emitted by the organic light-emitting layer EML directly passes through the transparent electrode serving as the anode and is emitted from the base substrate. Further part of the light emitted by the organic light-emitting layer EML propagates to the reflecting electrode serving as the cathode, and the reflecting electrode reflects the further part of the light. The reflected light resonates with each other, and meanwhile, the reflected light resonates with the light propagated by the organic light-emitting layer EML to the transparent electrode, thereby forming a microcavity effect and improving the light emitting brightness of the organic light-emitting diode. It may be understood that a part of the light from the organic light-emitting layer EML of the top-emitting organic light-emitting diode directly emits out of the cathode, and further part of the light is reflected through the metal anode, which can also form microcavity effect and improve the light emitting brightness of the organic light-emitting diode. Top-emitting organic light-emitting diodes may be used or bottom-emitting organic light-emitting diodes may be used. The bottom-emitting organic light-emitting diode is used as an example in the embodiments of the present disclosure.

As shown in FIG. 1, the light-emitting element in an embodiment of the present disclosure is provided with a first electrode 203, a light-emitting layer 204 and a second electrode 205 in sequence on the functional layer 201. An orthographic projection of the second electrode 205 on the functional layer 201 completely covers an orthographic projection of the light-emitting layer 204 on the functional layer 201, and the orthographic projection of the light-emitting layer 204 on the functional layer 201 completely covers an orthographic projection of the first electrode 203 on the functional layer 201. The first electrode 203 is a transparent electrode and serves as an anode of the light-emitting element. The second electrode 205 is a reflecting electrode and serves as a cathode of the light-emitting element. It may be understood that the second electrode 205 completely covers the light-emitting layer 204 so that the light emitted from the light-emitting layer 204 can be reflected as much as possible and the light emitting brightness of the light-emitting element can be improved.

It should be noted that the material of the second electrode 205 may be any one of aluminum (Al), silver (Ag), titanium (Ti), and molybdenum (Mo), or an alloy of any of the above, and the material of the first electrode 203 may be indium tin oxide (ITO) or other conductive materials with good light transmittance. The specific materials of the first electrode 203 and the second electrode 205 are not further limited in the embodiments of the present disclosure.

As shown in FIG. 2, the light-emitting layer 204 in an embodiment of the present disclosure comprises a hole injection layer HIL, a hole transport layer HTL, an electron block layer EBL, an organic light-emitting layer EML, a hole block layer HBL, and an electron transport layer ETL disposed in sequence in a direction away from the first electrode 203 on the functional layer 201. The first electrode 203 is a transparent electrode and serves as an anode, and the second electrode 205 is a reflecting electrode and serves as a cathode. With the voltage applied to the anode and the cathode, holes and electrons are injected from the anode and the cathode respectively, enter the HOMO (highest occupied molecular orbital) energy level of the hole transport layer HTL and the LUMO (lowest unoccupied molecular orbital) energy level of the electron transport layer ETL respectively, and then transition to the organic light-emitting layer EML to meet each other and form electron-hole pairs, i.e., excitons. Excitons in the excited state of molecules are released in the form of photons, which makes the organic light-emitting layer EML to emit visible light. A part of the visible light emitted from the organic light-emitting layer EML is emitted from the first electrode 203 serving as an anode, and the other part propagates to the second electrode 205 serving as a cathode and is reflected by the second electrode 205, and then emitted from the first electrode 203. In this process, the light emitted by the second electrode 205 resonates with each other, and the reflected light also resonates with the light directly propagated from the organic light-emitting layer EML to the first electrode 203, thereby forming a microcavity effect and improving the light emitting brightness of the light-emitting element.

It should be noted that in order to improve the light emitting quality, the thickness or the number of layers of the above-mentioned various light-emitting layers 204 may be changed, and the materials of the various layers may also be changed. In the present disclosure, the thickness, the number of layers and the materials of the various layers of the light-emitting layer 204 are not further limited.

As shown in FIG. 3, the light-emitting module in an embodiment of the present disclosure comprises a first base substrate 101, and a functional layer 201 and at least one light-emitting element disposed in sequence on the first base substrate 101. The functional layer 201 is configured to convert the light emitted by the light-emitting element into the light of a specific color, and provided with at least three sub-functional layers in sequence in a direction away from the first base substrate 101. The sub-functional layer comprises a first sub-functional layer 2011 and a second sub-functional layer 2012, the first sub-functional layer 2011 and the second sub-functional layer 2012 are alternately arranged. The refractive index of the first sub-functional layer 2011 is greater than that of the second sub-functional layer 2012. The refractive index of the first sub-functional layer 2011 is different from that of the second sub-functional layer 2012, the color of the light emitted by the light-emitting element when passing through the functional layer 201 can be changed by alternately arranging the two sub-functional layers, realizing multi-color display of the light-emitting module. It may be understood that the light-emitting module may have one light-emitting element or a plurality of light-emitting elements, and the number of light-emitting elements can be adjusted according to actual usage.

In some examples, the material of the first sub-functional layer 2011 is silicon nitride or silicon oxynitride, and the refractive index of the material is 1.6-2.0. The material of the second sub-functional layer 2012 is silicon oxide, and the refractive index of the material is 1.2-1.6. The first sub-functional layer 2011 and the second sub-functional layer 2012 are required to be alternately arranged in order to achieve multiple refraction of the light through the functional layer 201 and filter out the desired light of a specific color.

Further, the functional layer 201 may comprise at least three sub-functional layers including a first sub-functional layer 2011 and a second sub-functional layer 2012 arranged alternately. It may be understood that the functional layer 201 may have three or more sub-functional layers, for example: four sub-functional layers, with two first sub-functional layers 2011 and two second sub-functional layers 2012; or five or six sub-functional layers. The material of the first sub-functional layer 2011 is silicon nitride or silicon oxynitride, and therefore the material of the first sub-functional layer 2011 can be SiNₓ. The material of the second sub-functional layer 2012 is silicon oxide, and therefore the material of the second sub-functional layer 2012 can also be SiO₂. The embodiments of the present disclosure are illustrated by taking the functional layer 201 as an example that has three sub-functional layers in which the material of the first sub-functional layer 2011 is SiNₓ, and the material of the second sub-functional layer 2012 is SiO₂.

TABLE 1

| Sample | | | | | CIE | |
|---|---|---|---|---|---|---|
| number | Mo | SiNₓ | SiO₂ | SiINₓ | CIE-X | CIE-Y |
| 1 | 330 nm | 66 nm | 50 nm | 66 nm | 0.4592 | 0.4517 |
| 2 | | | 70 nm | | 0.4244 | 0.3227 |
| 3 | | | 90 nm | | 0.3046 | 0.1807 |
| 4 | | | 110 nm | | 0.1892 | 0.1690 |
| 5 | | | 130 nm | | 0.1766 | 0.2477 |
| 6 | | | 150 nm | | 0.2214 | 0.3243 |
| 7 | | | 170 nm | | 0.3131 | 0.4256 |
| 8 | | | 190 nm | | 0.3782 | 0.4687 |

FIG. 4 is a schematic structural diagram of a functional layer provided by an embodiment of the present disclosure. As shown in FIG. 4 and Table 1, in the embodiment of the present disclosure, the functional layer 201 comprises three sub-functional layers, two of which are the first sub-functional layers 2011 and one of which is the second sub-functional layer 2012. The second sub-functional layer 2012 is sandwiched between the two first sub-functional layers 2011. As shown in Table 1, the two first sub-functional layers 2011 have the same thickness and refractive index, with the thickness of 66 nm, and they are all SiNₓ thin films. During the experiment, molybdenum (Mo) with a thickness of 330 nm is used as the second electrode 205. The color of the light transmitted through the functional layer 201 can be changed by changing the thickness of the second sub-functional layer 2012. Finally, when the light with the same color is transmitted toward the second electrode 205, the CIE coordinate of the light of a specific color is generated by the reflected light from the second electrode 205 when passing through the functional layer 201 corresponding to the second sub-functional layer 2012 with different thicknesses.

Further, as shown in Table 1, during the experiment, the thicknesses of the two first sub-functional layers 2011 for all of the samples are kept at 66 nm, and the thickness of the metal molybdenum (Mo) layer for reflection is 330 nm. The color of light is changed by changing the thickness of the second sub-functional layer 2012 sandwiched between the two first sub-functional layers 2011. As shown in Table 1, in sample 1, the thickness of the second sub-functional layer 2012 is 50 nm. Under this condition, the CIE coordinate of the colors of the light reflected from the molybdenum (Mo) layer and refracted through the three sub-functional layers is (0.4592, 0.4517), and the corresponding colors under this coordinate are red series. Applying the thickness combination of sample 2 to the light-emitting module can make the light-emitting module emit orange-red light. In sample 2, the thickness of the second sub-functional layer 2012 is 70 nm. Under this condition, the CIE coordinate of the colors of the light reflected from the molybdenum (Mo) layer and refracted through the three sub-functional layers is (0.4244, 0.3227), and the corresponding colors under this coordinate are red series. Applying the thickness combination of sample 2 to the light-emitting module can make the light-emitting module emit light of red series. In sample 5, the thickness of the second sub-functional layer 2012 is 130 nm. Under this condition, the CIE coordinate of the colors of the light reflected from the molybdenum (Mo) layer and refracted through the three sub-functional layers is (0.1766, 0.2477), and the corresponding colors under this coordinate are blue series. Applying the thickness combination of sample 5 to the light-emitting module can make the light-emitting module emit light of blue series. In sample 7, the thickness of the second sub-functional layer 2012 is 170 nm. Under this condition, the CIE coordinate of the colors of the light reflected from the molybdenum (Mo) layer and refracted through the three sub-functional layers is (0.3131, 0.4256), and the corresponding colors under this coordinate are green series. Applying the thickness combination of sample 7 to the light-emitting module can make the light-emitting module emit light of green series. The thickness of the second sub-functional layer 2012 in sample 3 is 90 nm, and the reflected and emitted light is purple; the thickness of the second sub-functional layer 2012 in sample 4 and sample 6 are 110 nm and 150 nm, respectively, and both reflect and emit light of blue series; and the thickness of the second sub-functional layer 2012 in sample 8 is 190 nm, and the reflected and emitted light is yellow. Taking three sub-functional layers, in which a second sub-functional layer 2012 is sandwiched between two first sub-functional layers 2011, as an example, the CIE coordinate of the color of the light refracted through the three sub-functional layers can be changed by changing the thickness of the second sub-functional layer 2012 located in the middle. When the aforementioned functional layers are used in the light-emitting module, the light-emitting module can emit light of a specific color. The samples in Table 1 are only a part of the examples of the embodiments of the present disclosure. CIE coordinate of the light other than the eight samples in Table 1 can be obtained by changing the thickness of the second sub-functional layer 2012, or changing the thicknesses of the first sub-functional layer and the molybdenum (Mo) layer, for use on a display module, so that the display module emits the light of more kinds of specific colors.

It should be noted that the thickness and material of the first sub-functional layer 2011, the material of the second sub-functional layer 2012 and the material of the second electrode 205 in the present disclosure can be changed or adjusted according to specific products. For example, the silicon nitride material used in the first sub-functional layer 2011 is SiNₓ, and the silicon oxide material used in the second sub-functional layer 2012 can be SiO₂. The above exemplary examples are only used to better illustrate the technical solutions in the present disclosure and the thicknesses of the first sub-functional layer 2011, the second sub-functional layer 2012 and the second electrode 205 are not further limited.

It may be understood that the functional layer 201 is added in the light-emitting module of the present disclosure in order to realize multi-color display. There is no need to modify the organic light-emitting diode for the light-emitting element and therefore the mask cost is not increased. At the same time, the organic light-emitting diode can be made to emit light in monochrome. Therefore, changing the color of the light-emitting module using the functional layer 201 can also simplify part(s) of the manufacturing process of organic light-emitting diodes.

In some examples, the functional layer 201 comprises at least three sub-functional layers. At least one first sub-functional layer 2011 and at least one second sub-functional layer 2012 are comprised in the multi-layer sub-functional layers, and the first sub-functional layer 2011 and the second sub-functional layer 2012 are alternately arranged. One of the sub-functional layers closest to the light-emitting element is the first sub-functional layer. It may be understood that the first sub-functional layer 2011 having a high refractive index is preferentially disposed at the place close to the first electrode 203, and the light reflected by the second electrode 205 firstly passes through the first sub-functional layer 2011 having a high refractive index.

In some examples, the functional layer 201 comprises at least three sub-functional layers. At least one first sub-functional layer 2011 and at least one second sub-functional layer 2012 are comprised in the multi-layer sub-functional layers, and the first sub-functional layer 2011 and the second sub-functional layer 2012 are alternately arranged. One of the sub-functional layers closest to the light-emitting element is the second sub-functional layer. It may be understood that the second sub-functional layer 2012 having a low refractive index can also be preferentially disposed at the place close to the first electrode 203, and the light reflected by the second electrode 205 firstly passes through the second sub-functional layer 2012 having a low refractive index.

In some examples, the light-emitting module further comprises a second base substrate 102 disposed opposite to the first base substrate 101 and a reflecting layer 103 disposed on a side of the second base substrate 102 away from the light-emitting element. The second electrode 205 in the light-emitting element is a reflecting electrode for reflecting visible light emitted from the light-emitting layer 204 to the first base substrate 101. The reflecting layer 103 is disposed in the direction of the second electrode 205 of each light-emitting element away from the first base substrate 101 for light emitting. The reflecting layer 103 can be used for reflecting the light, which is not reflected by the second electrode 205 in each light-emitting element, to the first base substrate 101 for light emitting, reducing the light loss caused by the part of light being not completely reflected by the second electrode 205 to the first base substrate 101 for light emitting, thereby increasing the effective light-emitting amount of the light-emitting module and improving the overall brightness of the light-emitting module. In order to make the reflecting layer 103 more effective, the orthographic projection of the reflecting layer on the first base substrate 101 covers the orthographic projection of the second electrode 205 of each light-emitting element on the first base substrate 101. It may be understood that the reflecting layer 103 integrally covers all the second electrodes 205 of each light-emitting element.

It should be noted that the material of the reflecting layer 103 may be the same as that of the second electrode 205, or may be different from that of the second electrode 205. The material of the reflecting layer 103 may be molybdenum (Mo), and may also be any one of aluminum (Al), silver (Ag), and titanium (Ti), or an alloy of any of the above. In the embodiments of the present disclosure, the material of the reflecting layer 103 is not further limited.

In some examples, the light-emitting module further comprises an encapsulation base 202 and an encapsulation structure 301, which are positioned at an edge of the light-emitting module and disposed between the first base substrate 101 and the second base substrate 102. The encapsulation base 202 is positioned on the side of the functional layer away from the first base substrate 101. The second electrode 205 of the light-emitting element positioned at the edge of the light-emitting module partially covers the encapsulation base 202. The encapsulation structure 301 is used to seal the edge of the light-emitting module so as to prevent water, oxygen or the like from entering the light-emitting module, causing damage to the light-emitting element or shortening the life of the light-emitting module.

In some examples, the encapsulation base 202 comprises a main body structure and a plurality of branch structures, and the encapsulation structure 301 is at least partially embedded in a gap formed between the respective branch structures. Through the branch structures, the overlapping area between the encapsulation structure and the encapsulation base is increased, so that the encapsulation structure is more stably fixed in the light-emitting module, and better packaging effect is achieved.

It should be noted that a layer of a second base substrate 102 may also be disposed between the reflecting layer 103 and the encapsulation structure 301. The material of the second base substrate 102 may be the same as that of the first base substrate 101, and may be glass or a material with excellent light-transmitting effect. The materials of the first base substrate 101 and the second base substrate 102 are not further limited here.

In a second aspect, an embodiment of the present disclosure provides a light-emitting device, comprising any one of the light-emitting module described above. The light-emitting device can be a taillight of a vehicle or other light-emitting devices using the organic light-emitting diode.

It is to be understood that the above embodiments are only exemplary embodiments employed for the purpose of illustrating the principles of the present invention, however, the present invention is not limited thereto. To those of ordinary skill in the art, various modifications and improvements may be made without departing from the spirit and substance of the present disclosure, and these modifications and improvements are also considered to be within the scope of the present disclosure.

1. A light-emitting module, comprising a first base substrate, and a functional layer and at least one light-emitting element disposed on the first base substrate;
wherein, the light-emitting element is provided with a first electrode, a light-emitting layer and a second electrode in sequence on the functional layer in a direction away from the first base substrate;
the functional layer is located on a side of the first electrode close to the first base substrate, and is configured to convert the light emitted by the light-emitting element into the light of a specific color; wherein the functional layer comprises N sub-functional layers disposed in sequence in a direction away from the first base substrate, and N≥3; and
the sub-functional layer comprises at least one first sub-functional layer and at least one second sub-functional layer; the first sub-functional layer and the second sub-functional layer are alternately arranged; and the refractive index of the first sub-functional layer is greater than the refractive index of the second sub-functional layer.

2. The light-emitting module according to claim 1, wherein, a material of the first sub-functional layer is silicon nitride or silicon oxynitride.

3. The light-emitting module according to claim 2, wherein, the refractive index of the material of the first sub-functional layer is 1.6-2.0.

4. The light-emitting module according to claim 1, wherein, a material of the second sub-functional layer is silicon oxide.

5. The light-emitting module according to claim 4, wherein, the refractive index of the material of the second sub-functional layer is 1.2-1.6.

6. The light-emitting module according to claim 1, wherein, the functional layer comprises N sub-functional layers, and N≥3; and one of the sub-functional layers closest to the light-emitting element is the first sub-functional layer.

7. The light-emitting module according to claim 1, wherein, the functional layer comprises N sub-functional layers, and N≥3; and one of the sub-functional layers closest to the light-emitting element is the second sub-functional layer.

8. The light-emitting module according to claim 1, wherein, when the light-emitting color of the light-emitting module is orange, the functional layer comprises two layers of the first sub-functional layer and the second sub-functional layer sandwiched between the two layers of the first sub-functional layer; a thickness of the first sub-functional layer is 66 nm; and a thickness of the second sub-functional layer is 50 nm.

9. The light-emitting module according to claim 1, wherein, when the light-emitting color of the light-emitting module is red, the functional layer comprises two layers of the first sub-functional layer and the second sub-functional layer sandwiched between the two layers of the first sub-functional layer; a thickness of the first sub-functional layer is 66 nm; and a thickness of the second sub-functional layer is 70 nm.

10. The light-emitting module according to claim 1, wherein, the first electrode is a transparent electrode; and the second electrode is a reflecting electrode.

11. The light-emitting module according to claim 1, wherein, the light-emitting module further comprises a second base substrate disposed opposite to the first base substrate and a reflecting layer disposed on a side of the second base substrate away from the light-emitting element; and
an orthographic projection of the reflecting layer on the first base substrate covers an orthographic projection of the second electrode of each of the light-emitting elements on the first base substrate.

12. The light-emitting module according to claim 11, wherein, the light-emitting module further comprises an encapsulation base and an encapsulation structure, which are positioned at an edge of the light-emitting module and disposed between the first base substrate and the second base substrate;
the encapsulation base is positioned on a side of the functional layer away from the first base substrate; and the second electrode of the light-emitting element positioned at the edge of the light-emitting module partially covers the encapsulation base; and
the encapsulation structure is used for sealing the edge of the light-emitting module.

13. The light-emitting module according to claim 12, wherein, the encapsulation base comprises a main body structure and a plurality of branch structures; and the encapsulation structure is at least partially embedded in a gap formed between the respective branch structures.

14. A light-emitting device, comprising the light-emitting module according to claim 1.
